(19) United States
(12) Patent Application Publication
(10) Pub. No.: US 2024/0169133 A1
(43) Pub. Date: May 23, 2024

(54) Apparatus, Device, Method and Computer Program for Generating an RTL Representation of a Circuit

(71) Applicants: Theo DRANE, El Dorado Hills, CA (US); Samuel COWARD, London (GB); George CONSTANTINIDES, London (GB)

(72) Inventors: Theo DRANE, El Dorado Hills, CA (US); Samuel COWARD, London (GB); George CONSTANTINIDES, London (GB)

(21) Appl. No.: 18/391,716

(22) Filed: Dec. 21, 2023

Related U.S. Application Data
(60) Provisional application No. 63/487,272, filed on Feb. 28, 2023.

(51) Int. Cl. G06F 30/327; G06F 30/337

(52) U.S. Cl. CPC G06F 30/327; G06F 30/337

(57) ABSTRACT

An example relates to an apparatus for generating a register transfer level (RTL) representation of a circuit, the apparatus comprising interface circuitry, machine-readable instructions and processing circuitry to execute the machine-readable instructions to generate a graph representation of the circuit, the graph representation comprising a first set of vertices representing operators and a second set of vertices representing operands of the graph representation of the circuit. The processing circuitry is to execute the machine-readable instructions to identify one or more conditional operators, with each conditional operator defining at least two possible outcomes depending on the condition, and with each possible outcome being represented by a branch of the graph representation of the circuit. The processing circuitry is to execute the machine-readable instructions to determine, for the possible outcomes of the one or more conditional operators, a condition imposed by the respective outcome. The processing circuitry is to execute the machine-readable instructions to annotate at least a subset of the vertices of the respective branches representing the possible outcomes with the condition imposed by the corresponding outcome. The processing circuitry is to execute the machine-readable instructions to generate an RTL representation of the circuit based on the graph representation of the circuit.

### BACKGROUND

The design of hardware circuits is often performed through different levels of abstraction, from high-level hardware description languages to the low-level design of the transistors and other components. One abstraction level is the so-called register transfer level (RTL) abstraction level, which is used in hardware description languages like Verilog or VHDL (Very High Speed Integrated Circuits Hardware Description Language). A representation of a circuit on the RTL abstraction level is subsequently synthesized to a netlist, and ultimately to a circuit design to be used for manufacturing the integrated circuit.

Hardware languages provide a multitude of possibilities for implementing a given functionality, leading to a large design space. Such a large design space may render any improvement or optimization of the circuit design more difficult, as the number of possible implementations is large, and an estimation of the hardware implementation cost often is not straightforward.

High level-synthesis tools are known to deploy interval arithmetic, a weak program analysis technique, that enables simple optimizations, such as bitwidth reduction. However, Interval arithmetic fails to capture relationships between variables, which makes it easy to compute, but results in weak approximations. For example, it will not recognize that abs_diff≤0 in the following code: let abs_diff=(a>b)?a−b:b−a;. In software development, complex program analysis deploys “Zone/Octagon abstract domains”, which can encode relationships between variables. However, such techniques are not used in EDA (Electronic Design Automation) tools being used for circuit design and are generally not applied to the field of hardware design. When hardware is designed manually, the designer may rely on constrained evaluation to achieve the greatest performance. However, manual hardware design is generally considered to be time-consuming, bug-prone and expensive.

### BRIEF DESCRIPTION OF THE FIGURES

Some examples of apparatuses and/or methods will be described in the following by way of example only, and with reference to the accompanying figures, in which:

FIG. 1a shows a schematic diagram of an example of an apparatus an apparatus 10 or device 10 for generating a register transfer level (RTL) representation of a circuit, and of a computer system 100 comprising such an apparatus 10 or device 10;

FIGS. 1b and 1c show flow charts of examples of a method for generating an RTL representation of a circuit;

FIG. 2 shows a schematic diagram of a Register Transfer Level (RTL) design;

FIG. 3 shows a graph of an absolute difference RTL;

FIGS. 4a and 4b show two schematic diagrams of floating point subtractor designs;

FIGS. 5a and 5b show an example of an equivalency graph before and after rewriting;

FIG. 6 shows a table of ASSUME node rewrites;

FIG. 7 shows a table of condition rewrites;

FIG. 8 shows results of an impact of a proposed optimization approach; and

FIG. 9 shows a table of logic synthesis results.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

In the following description, specific details are set forth, but examples of the technologies described herein may be practiced without these specific details. Well-known circuits, structures, and techniques have not been shown in detail to avoid obscuring an understanding of this description. “An example/example,” “various examples/examples,” “some examples/examples,” and the like may include features, structures, or characteristics, but not every example necessarily includes the particular features, structures, or characteristics.

Some examples may have some, all, or none of the features described for other examples. “First,” “second,” “third,” and the like describe a common element and indicate different instances of like elements being referred to. Such adjectives do not imply element item so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform or resource, even though the instructions contained in the software or firmware are not actively being executed by the system, device, platform, or resource.

The description may use the phrases “in an example/example,” “in examples/examples,” “in some examples/examples,” and/or “in various examples/examples,” each of which may refer to one or more of the same or different examples. Furthermore, the terms “comprising,” “including,” “having,” and the like, as used with respect to examples of the present disclosure, are synonymous.

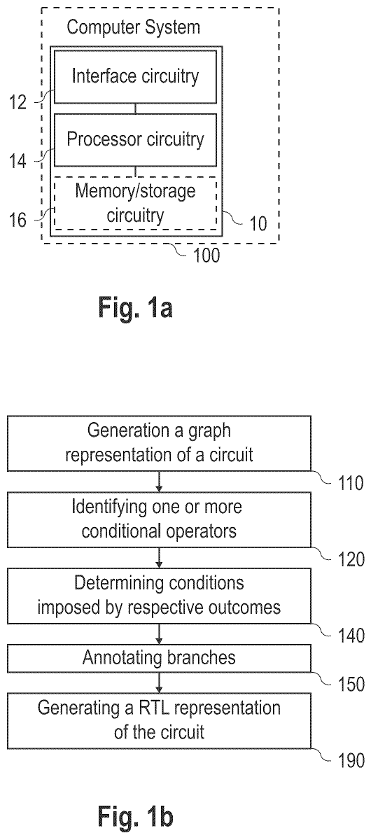

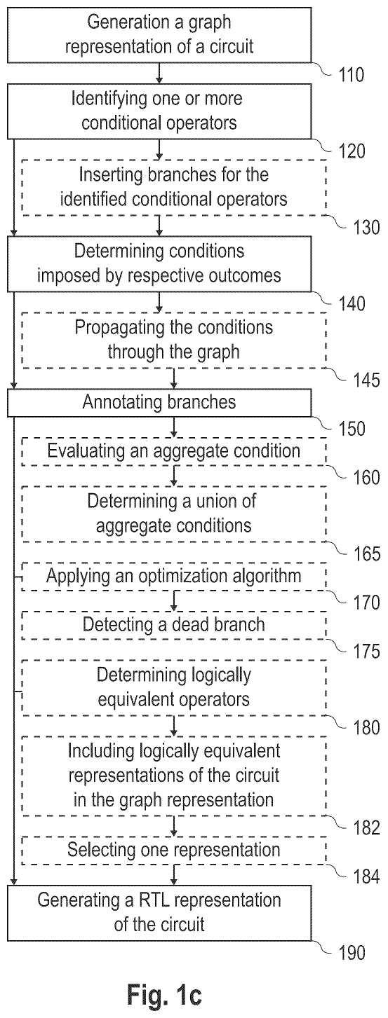

FIG. 1a shows a schematic diagram of an example of an apparatus an apparatus 10 or device 10 for generating a register transfer level (RTL) representation of a circuit, and of a computer system 100 comprising such an apparatus 10 or device 10. The apparatus 10 comprises circuitry to provide the functionality of the apparatus. For example, the circuitry of the apparatus may be configured to provide the functionality of the apparatus. For example, the apparatus of FIG. 1a comprises interface circuitry 12, processing circuitry 14 and (optional) storage circuitry 16. For example, the processing circuitry may be coupled with the interface circuitry and with the storage circuitry. For example, the processing circuitry may provide the functionality of the apparatus, in conjunction with the interface circuitry (for exchanging information, e.g., with other components inside or outside a computer system comprising the apparatus or device) and the storage circuitry (for storing information, such as machine-readable instructions). Likewise, the device 10 may comprise means for providing the functionality of the device. For example, the means may be configured to provide the functionality of the device. The components of the device are defined as component means, which may correspond to, or implemented by, the respective structural components of the apparatus. For example, a corresponding device comprises means for processing 14, which may correspond to or be implemented by the processing circuitry, means for communicating 12, which may correspond to or be implemented by the interface circuitry, and (optional) means for storing information 16, which may correspond to or be implemented by the storage circuitry. In general, the functionality of the processing circuitry or means for processing may be implemented by the processing circuitry or means for processing executing machine-readable instructions. Accordingly, any feature ascribed to the processing circuitry or means for processing may be defined by one or more instructions of a plurality of machine-readable instructions. The apparatus or device may comprise the machine-readable instructions, e.g., within the storage circuitry or means for storing information.

The processing circuitry or means for processing is to generate a graph representation of the circuit, the graph representation comprising a first set of vertices representing operators and a second set of vertices representing operands of the graph representation of the circuit. The processing circuitry or means for processing is to identify one or more conditional operators, with each conditional operator defining at least two possible outcomes depending on the condition, and with each possible outcome being represented by a branch of the graph representation of the circuit. The processing circuitry or means for processing is to determine, for the possible outcomes of the one or more conditional operators, a condition imposed by the respective outcome. The processing circuitry or means for processing is to annotate at least a subset of the vertices of the respective branches representing the possible outcomes with the condition imposed by the corresponding outcome. The processing circuitry or means for processing is to generate an RTL representation of the circuit based on the graph representation of the circuit.

FIGS. 1b and 1c show flow charts of examples of a corresponding method for generating an RTL representation of a circuit, which may be performed by a computer system, such as the computer system 100, and in particular by the apparatus 10 or device 10 of the computer system 100. The method comprises generating 110 the graph representation of the circuit. The method comprises identifying 120 the one or more conditional operators. The method comprises determining 140, for the possible outcomes of the one or more conditional operators, the condition imposed by the respective outcome. The method comprises annotating 150 the at least a subset of the vertices of the respective branches representing the possible outcomes with the condition imposed by the corresponding outcome. The method comprises generating 190 the RTL representation of the circuit based on the graph representation of the circuit.

In the following, the features of the apparatus 10, the device 10, the computer system 100, the method and of a corresponding computer program will be described in more detail with reference to the apparatus 10. Features introduced in connection with the apparatus 10 may likewise be included in the corresponding device 10, computer system 100, method and computer program.

The present disclosure relates to a process for improving or optimizing a circuit design. Circuit design is a complex process that typically follows several stages, from conceptualization and specification through to implementation and testing. An RTL, or Register-Transfer Level, representation plays a crucial role during the design of digital circuits, particularly when dealing with integrated circuits (ICs) and complex system-on-chips (SoCs). RTL provides a way to describe the behavior of a circuit at the abstraction level of registers and the transfer of data between them. It allows designers to specify the operation of a circuit in terms of data flow and control flow without being concerned with low-level (gate-level) details. RTL representations are used as input for synthesis tools which automatically convert the high-level descriptions into gate-level descriptions, which are needed for actual fabrication. This involves converting the RTL code, which is usually written in hardware description languages (HDLs) like VHDL or Verilog, into a netlist of logic gates and other low-level components. During synthesis, various optimizations for speed, area, power consumption, and other factors can be applied to the RTL code to generate an efficient gate-level design.

The present disclosure provides an optimization that is applied prior to synthesis, in which annotations are used to identify options for optimizing the RTL code being used to implement the circuit design. In particular, in the proposed concept, the circuit design is first converted into a graph representation. Within the graph representation, conditional operators are being detected and used to specify different branches, depending on the conditions imposed by the respective conditional operators. These different branches may then be optimized separately, which can improve the inherent delay and/or die area of the respective branches, resulting in an overall faster design that may use less die space. Moreover, by evaluating conditions imposed on the respective branches by multiple conditional operators, even greater optimizations become possible, as constraint-based optimizations can be performed. In the present disclosure, when the term “optimization” is used, the result is not necessarily the optimal result with respect to any or all criteria. In the present disclosure, an optimization is a state or result that is better, with respect to at least one criterion, than a state preceding the optimized state. In general, the proposed concept may be used for improving or optimizing an existing RTL design. Accordingly, the processing circuitry may generate the graph representation from a further RTL representation of the circuit.

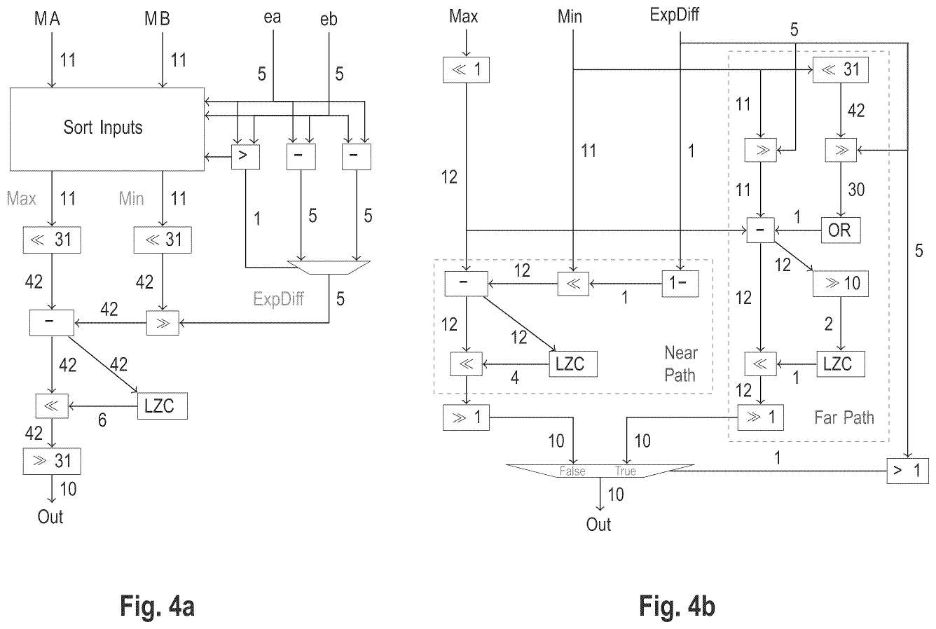

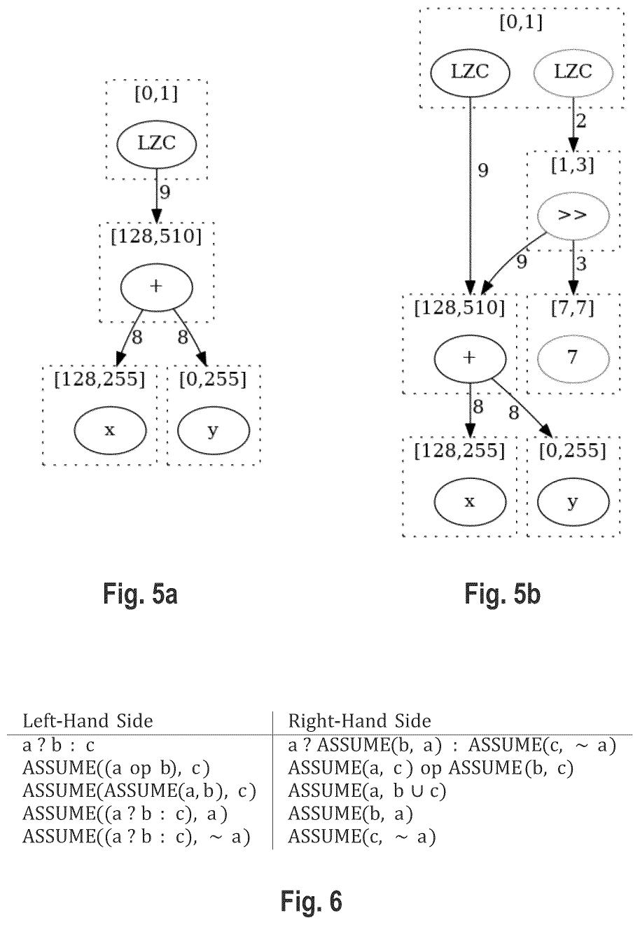

The process starts with generating the graph representation of the circuit. In graph representations, subject-matter is defined by the vertices and edges of the graph. In the present case, the graph representation comprises a first set of vertices representing operators and a second set of vertices representing operands of the graph representation of the circuit. The edges represent the connections between the operators, and between the operands and the operators of the circuit. The edges thus represent the data flow between the operators, with the operands feeding into the operators according to the data flow defined by the edges. In effect, the graph representation may be a data-flow graph representing the circuit. Examples of such a graph representation are shown in FIGS. 4a, 4b, 5a and 5b. For example, in FIG. 4a, MA, MB, ea, and eb are operands, the “−” operators are subtractors and the “<<” and “>>” operators are bit-shift operators. Similarly, in FIG. 4b, Max, Min and Exp Diff are operands, the “−” operators are subtractors, the “<<” and “>>” operators are bit-shift operators, and the “OR” operator is an OR gate and the “LZC” operator is a leading zero counter operator. Similarly, in FIGS. 5a and 5b, x, y and 7 are the operands, and “+”, “>>” and “LZC” are the operators. In some cases, e.g., as shown in FIGS. 4a and 4b, the edges may further include annotations (shown beside the edges in FIGS. 4a and 4b) representing the bit-width of the data flow between the different operators or operands and operators. For example, the processing circuitry may include a bit-width of the operands in the graph representation as edge labels of the edges between the vertices representing the operands and the vertices representing the operators accessing the operands.

The proposed technique is in the following also denoted constraint-aware datapath optimization and is based on identifying constraints that are inherent to the design. One source of such constraints is the use of conditional operators. In the context of RTL design and digital logic, conditional operators are not a formal concept like they are in high-level programming languages (e.g., if-else statements or ternary operators like ? :). Instead, in RTL, the behavior of a digital system is described in terms of the flow of data between hardware registers and the logical operations that are performed on that data. Conditional behavior in RTL is then implemented using constructs such as multiplexers (muxes), decoders, and conditional logic statements in the hardware description language (HDL) that is used to describe the RTL. For example, in Verilog (a popular HDL), conditional logic can be defined using if, case, and the conditional operator (? :), which allow to describe dynamic behavior based on the value of signals. Such conditional operators (e.g., if, case, and ?) are identified in the circuit design (e.g., in the further RTL representation, or in the graph representation). Each conditional operator defines at least two possible outcomes depending on the condition. For example, both the “if” and the “?” conditional operator define the outcome that the condition is met and the outcome that the condition is not met. A “case” conditional operator defines the outcomes according to the cases being defined (e.g., at least a first case being defined and a default case). For each of the outcomes, a branch is defined in the graph representation of the circuit. In other words, each possible outcome is represented by a branch of the graph representation of the circuit. The respective branches representing the possible outcomes are data paths, from the operands through the operators towards a root of the graph representation. Once the respective branches are identified, they can be inserted into the graph representation, if this has not happened while generating the graph representation. For example, the processing circuitry may insert, for the identified conditional operators, the branches representing the possible outcomes of the one or more conditional operators (into the graph representation). Accordingly, as shown in FIG. 1b, the method may comprise inserting 130, for the identified conditional operators, with the branches representing the possible outcomes of the one or more conditional operators.

The optimization applied by the proposed algorithm is based on determining the conditions applied on the respective branches. To give an example, shown in FIG. 5a, if it is known, that of two values x, y being added, one is in the range [128, 255] and the other is in the range [0, 255], it is clear that the result lies in the range [128, 510]. The cases of the result being lower than 128 or higher than 510 do not need to be handled, which may enable additional optimizations. It is clear that the conditions can not only be imposed by conditional operators, but also by annotating the further RTL representation with constraints on the range of values of operands. In other words, in addition to determining, for the possible outcomes of the one or more conditional operators, a condition imposed by the respective outcome, the processor circuitry may further determine, for constraints imposed upon operands, the condition imposed by the constraints imposed upon the respective operands. The conditions may then be propagated through the graph, e.g., from the leaves towards the root of the graph. In other words, the processing circuitry may propagate the conditions imposed by the respective outcomes (and, optionally, constraints) through the graph. Accordingly, as further shown in FIG. 1c, the method may comprise propagating 145 the conditions imposed by the respective outcomes (and, optionally, constraints) through the graph. In the example of FIG. 5a, the constraint imposed on the operands x, y is propagated through the graph, resulting in the condition [128, 510] at the addition operator. Once the conditions have been determined and propagated through the graph, at least a subset of the vertices of the respective branches representing the possible outcomes are annotated with the (propagated) condition imposed by the corresponding outcome. For example, this can be done by adding additional vertices that represent the respective conditions. In other words, the processing circuitry may annotate at least the subset of the vertices of the respective branches representing the possible outcomes with the condition imposed by the corresponding outcome by inserting a third set of vertices representing the conditions into the graph and inserting edges between the vertices being annotated and the vertices representing the respective conditions.

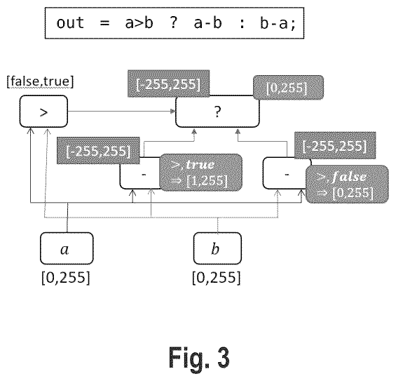

Referring again to the example of FIG. 5a, the condition annotated at the “+” addition operator is the constrained value interval [128, 510], which is the result of the constrained value intervals [128, 255] and [0, 255] imposed upon the operands x and y, respectively. To arrive at the constrained value interval of [128, 510] for the addition operator, the conditions imposed by the constraints are combined. In other words, the processing circuitry may evaluate, for the branches representing the possible outcomes, an aggregate condition based on one or more conditions the vertices of the respective branches are annotated with. The processing circuitry may to determine, for at least the vertices representing conditional operators, a union of the aggregate conditions evaluated for the branches representing the possible outcomes connected to the vertex representing the respective conditional operator. Accordingly, as further shown in FIG. 1c, the method may comprise evaluating 160, for the branches representing the possible outcomes, an aggregate condition based on one or more conditions the vertices of the respective branches are annotated with, and determining 165, for at least the vertices representing conditional operators, a union of the aggregate conditions evaluated for the branches representing the possible outcomes connected to the vertex representing the respective conditional operator. To be more precise—if the condition imposed relates to interval arithmetic, i.e., to a range of possible values (i.e., constrained value intervals) for the operands and results of operations, the resulting union of the conditions may also define a constrained value interval. In other words, the condition imposed by the respective conditional operator (or by the constraint on the respective operands) may be related to interval arithmetic. The processing circuitry may evaluate, for the branches representing the possible outcomes, one or more constrained value intervals for one or more of the operands based on one or more conditions the vertices of the respective branches are annotated with (e.g., according to a conditional operator or according to a constraint). The processing circuitry may determine, for at least the vertices representing conditional operators, a union of the constrained value intervals evaluated for the branches representing the possible outcomes connected to the vertex representing the respective conditional operator. An example of these kinds of conditions is shown in FIGS. 3, 5a and 5b.

Once the graph is generated and annotated, an optimization algorithm may be applied onto it. In other words, the processing circuitry may apply at least one optimization algorithm on the respective branches representing the possible outcomes, with the optimization algorithm being based on the condition imposed by the corresponding outcome. Accordingly, as further shown in FIG. 1c, the method may comprise applying 170 at least one optimization algorithm on the respective branches representing the possible outcomes, with the optimization algorithm being based on the condition imposed by the corresponding outcome. In general, at least one of the two following optimizations may be performed—an optimization that is based upon changing the operation(s) being used according to the condition(s) imposed upon the respective branches (e.g., by using a smaller addition/subtraction/multiplication operator, e.g., in combination with a bit shifter), and an optimization with respect to branches that cannot be reached according to the annotated conditions. In the former case, a condition-dependent branch-specific optimization may be applied on the respective branches. Examples for this kind of optimization are illustrated in connection with FIGS. 3, 4a, 4b, 5a and 5b, for example. Additionally, or alternatively, the processing circuitry may detect at least one dead branch within the graph-based representation based on the condition or conditions the vertices of the branch are annotated with. Accordingly, the method may comprise detecting 175 at least one dead branch within the graph-based representation based on the condition or conditions the vertices of the branch are annotated with. For example, the dead branch(es) may be removed from the graph representation.

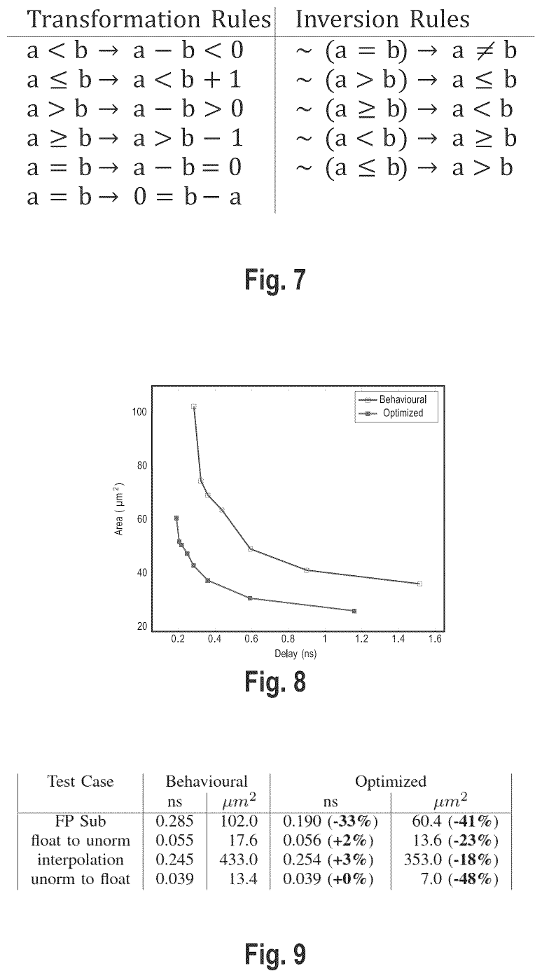

Another type of optimization that can be performed is based on how RTL designs are eventually synthesized onto a chip. In general, the synthesis of the RTL design yields various optimization opportunities, which depend on the routing between gates/transistors, process being used, the library of components being provided by the chip manufacturer etc. Depending on which optimizations are possible during synthesis in the respective case, slight modifications of the circuit/RTL design can yield big improvements, e.g., with respect to the delay being incurred and the die area being used. Another optional optimization technique is therefore to extend the graph to not only include the additional branches, but to also add alternatives into the graph. In this case, the graph representation may be based on an equivalence graph, which is a graph that includes, for at least some branches, multiple implementations that are logically equivalent, but slightly different with respect to implementation. For example, the processing circuitry may determine, for one or more operators represented by the one or more vertices of the first set of vertices of the graph, one or more logically equivalent operators. The processing circuitry may include the one or more logically equivalent operators in the graph representation, such that the graph representation comprises a plurality of logically equivalent representations of the circuit. Accordingly, as further shown in FIG. 1c, the method may comprise determining 180, for one or more operators represented by the one or more vertices of the first set of vertices of the graph, one or more logically equivalent operators, and including 182 the one or more logically equivalent operators in the graph representation, such that the graph representation may comprise a plurality of logically equivalent representations of the circuit. This can be achieved by using a set of transformations that can be used to transform operators into logically equivalent operators. In other words, the processing circuitry may determine the one or more logically equivalent operators based on a pre-defined set of logically equivalent transformations between operators. For example, in connection with FIGS. 6 and 7, and in the later stages of the documents, such transformations are discussed. In the present context, some additional logically equivalent transformations are enabled by the conditions imposed on the respective branches. Accordingly, the processing circuitry may determine the respective one or more logically equivalent operators based on at least one condition the vertex of the respective operator is annotated with and/or based on at least one condition a vertex inside a branch connected to the vertex of the respective operator is annotated with. The RTL representation of the circuit may then be generated based on one of the plurality of equivalent representations of the circuit.

By including multiple equivalent implementations into the same equivalence graph, the graph is extended heavily. However, in the RTL representation being generated, each branch and operator needs to be included only once, with the other alternatives being part of the equivalence graph being discarded. Therefore, the processing circuitry may select one representation from the plurality of logically equivalent representations of the circuit based on a selection criterion, and to generate the RTL representation based on the selected representation. Accordingly, as further shown in FIG. 1c, the method may comprise selecting 184 one representation from the plurality of logically equivalent representations of the circuit based on a selection criterion and generating the RTL representation based on the selected representation. When selecting one of the representations, not every representation may be equally favorable. For example, some representations may be more costly to manufacture as they require more silicon area. Some representations may have an increased power draw (also due to more silicon area or due to silicon structures that increase the power consumption). Some representations may yield a longer processing delay (when many operators have to be used in succession), limiting the maximal frequency of the circuit. Therefore, one of the representations may be selected that has desired properties with respect to aspects such as silicon area, power draw and processing delay. As outlined above, one possible selection criterion is the implementation cost (e.g., in terms of silicon area or power consumption). Accordingly, the representation may be selected based on an implementation cost of the representation. For example, the implementation cost may be based on at least one of a silicon area (or more general semiconductor area) required by the representation and a power consumption of the representation. Another possible criterion is the processing delay, i.e., how much time the circuit takes to provide its output based on the input. Accordingly, the representation may be selected based on a processing delay of the representation. The processing circuitry may be configured to determine the value underlying the selection criterion for the plurality of logically equivalent representations, i.e., of the implementation cost and/or processing delay, e.g., based on a database or data structure comprising information on the implementation cost and/or processing delay of the operators, and to select the representation based on a comparison of the determined values. The RTL representation of the circuit may then be generated based on one of the plurality of equivalent representations of the circuit, e.g., based on the selected representation. For example, the RTL representation may be derived from the graph representation, by using the operators and operands included in the representation.

Finally, the processing circuitry generates the RTL representation of the circuit based on the graph representation of the circuit. For example, the processing circuitry may be configured to output the generated RTL representation or representations, e.g., via a computer-readable medium or via a signal comprising the respective RTL representation or representations.

The interface circuitry 12 or means for communicating 12 may correspond to one or more inputs and/or outputs for receiving and/or transmitting information, which may be in digital (bit) values according to a specified code, within a module, between modules or between modules of different entities. For example, the interface circuitry or means for communicating may comprise circuitry configured to receive and/or transmit information.

For example, the processing circuitry 14 or means for processing 14 may be implemented using one or more processing units, one or more processing devices, any means for processing, such as a processor, a computer or a programmable hardware component being operable with accordingly adapted software. In other words, the described function of the processing circuitry or means for processing may as well be implemented in software, which is then executed on one or more programmable hardware components. Such hardware components may comprise a general-purpose processor, a Digital Signal Processor (DSP), a micro-controller, etc.

For example, the storage circuitry 16 or means for storing information 16 may comprise at least one element of the group of a computer readable storage medium, such as a magnetic or optical storage medium, e.g., a hard disk drive, a flash memory, Floppy-Disk, Random Access Memory (RAM), Programmable Read Only Memory (PROM), Erasable Programmable Read Only Memory (EPROM), an Electronically Erasable Programmable Read Only Memory (EEPROM), or a network storage.

For example, the computer system 100 may be a workstation computer system, i.e., a computer system that is used locally by an individual engineer, or a server computer system, i.e., a computer system being used to serve functionality, such as the selection of the representation and the generation of the code, to one or client computers.

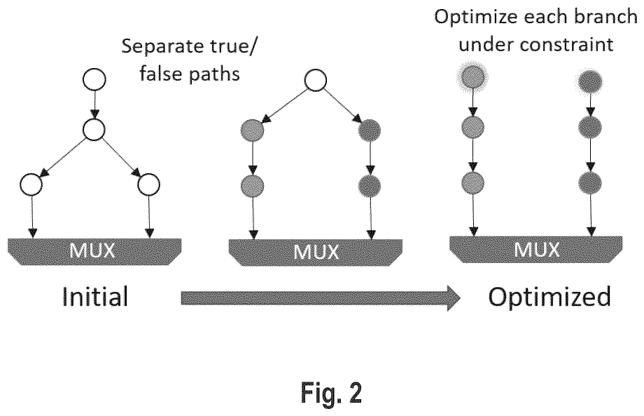

More details and aspects of the apparatus 10, device 10, computer system 100, method and computer program are mentioned in connection with the proposed concept or one or more examples described above or below (e.g., FIG. 2 to 4). The apparatus 10, device 10, computer system 100, method and computer program may comprise one or more additional optional features corresponding to one or more aspects of the proposed concept or one or more examples described above or below.

Various examples relate to a compiler-based approach to a datapath dominated circuit design problem, where only human based optimization and design currently achieves the required performance. Existing RTL optimization tools do not exploit input domain constraints or branch constraints when optimizing a design. The present disclosure provides a compiler-inspired program that automates this optimization using additional constraint awareness. Zones/Octagons are used as part of the proposed concept, in an enhanced from and applied to hardware design.

In the present disclosure, hardware designs are represented as a dataflow graph, in which additional signal range data and constraints are attached to nodes of the graph, that facilitate constraint-aware optimization. Conditional evaluations may be automatically propagated through the graph, removing the need for complex human reasoning about the consequences of the condition. Using graph rewriting techniques, conditions may be automatically simplified, and branches may be rewritten, to the extent that reasoning about the implications of a condition reduces to a simple syntactic check.

A human circuit optimization technique is to separate a design into multiple branches, for example the dual path floating point adder. The proposed concept may enable and automate such branch aware optimization. The proposed techniques may enable deeper optimizations, thus producing significantly improved hardware than other techniques, so that the proposed technique can be integrated into hardware design tools. While the proposed concept is primarily related to hardware design, it may be implemented across hardware and software stack to enable deep program analysis and optimization.

To demonstrate the motivation, a simple C-code example is given:

y=(x>0)?f abs(x):0;

An equivalent implementation would be:

y=(x>0)?x:0;

Due to the branch constraint, x>0, f abs(x) (absolute number of x) can be replaced with x, a non-valid transformation in general. This highlights how an optimizer may be constraint-aware to improve the optimizer's performance. Returning to hardware optimization, the proposed concept may enable dead branch detection and/or condition dependent branch optimization.

In the following, a short background is given on interval arithmetic. Interval arithmetic replaces variables/signals by their respective interval ranges that those signals can assume. then does computations on these intervals. Namely, suppose x, y∈[1, 2].

x+y→[1, 2]+[1, 2]=[2, 4]⇒x+y∈[2, 4]

Representing a hardware design as a dataflow graph, an evaluation can be associated, namely a union of intervals that the bits that comprise the signal can take, calculated via interval arithmetic.

In the following, a short background is given on condition dependent branch optimization. FIG. 2 shows a schematic diagram of a Register Transfer Level (RTL) design, containing a mux (short for multiplex, which is generally used to implement a conditional) between branches that share operations. The branches are separated, which allows optimizing each branch under the branch condition being true/false.

To capture the effect of the branch, when a mux statement (i.e., a condition) is encountered, the branches may be separated into two representations. On each branch, the signal values may be evaluated using interval arithmetic and optimized under the assumption that the branch condition is true/false. The condition may be pushed down to the leaves and the leaves may be evaluated under the assumed condition. The algorithm may then work back upwards computing the conditional evaluations.

At the mux node, the union of the two evaluations (one from each branch) is taken, allowing to evaluate the output more accurately. This technique allows to automatically optimize the above example y=(x>0)?f abs(x):0.

FIG. 3 highlights this analysis improvement. In FIG. 3, another example is shown, where out=a>b?a−b:b−a; FIG. 3 shows an absolute difference RTL (out=a>b?a−b:b−a, on top) and its respective graph (below). The naïve interval arithmetic approach (rectangular corners) stores an evaluation per node, suggesting that negative outputs are possible. The conditional evaluations (rounded corners) enable a tighter bound on the output. FIG. 3 is a simple example where the human quickly realizes the implication of the branching, but the computer fails with interval arithmetic because it is unaware of the constraints imposed by the branch.

More accurate program analysis can detect dead branches, that were previously thought to be live. Consider an additional branch in FIG. 2, where the false path would never be taken:

out>=0?c:d

Condition dependent branch optimizations are enabled by simple reasoning about the implications of the constraints on the specific datapath. In some examples of the proposed concept, this may involve computing a constrained interval arithmetic, where common variables encountered in the constraints and datapath are detected and the constraints are applied on these. This reasoning proves the validity of additional more typical optimizations since they only need to hold on a constrained sub-domain

To illustrate how condition dependent branch optimizations are enabled, consider the subtraction of two positive floats:

2^{ea}×1.ma−2^{eb}×1.mb

There are 3 main stages to the hardware implementation:
1. Alignment: compute |ea−eb| and shift the corresponding mantissa
2. Subtraction
3. Renormalize—ensure output has a leading one

A conventional optimized hardware implementation may case-split on |ea−eb|>1, with the true branch being referred to as the far path and the false branch being referred to as the near path. Each path can now be independently optimized if the implications of the branch condition on each path are known.

Using the conditional evaluation analysis described above the consequences of the assumed conditions can be computed, which enable further optimizations. For example, on the far path, the resulting subtraction produces a result which requires only a small renormalization. This was automatically detected and applied using the proposed concept, as shown in FIGS. 4a and 4b. FIGS. 4a and 4b show two schematic diagrams of floating point subtractor designs, where the right-hand side is the result of an automated constraint aware optimization implemented using the proposed concept. The left-hand side (FIG. 4a) shows behavioral architecture, using a 42 bit subtraction. The right-hand side (FIG. 4b) shows a dual path optimized architecture, using two 12-bit subtractors. The Near path uses a one-bit alignment shift, followed by a larger renormalization stage. The far path uses a 12-bit alignment shift and a single bit renormalization.

In the following, an example of simplified conditional reasoning is provided. In general, reasoning about the consequences of arbitrary constraints imposed via mux branches, which could branch based on any intermediate signal in the design, is difficult. Firstly, in the case of compound conditions, such as a∨b, it can be beneficial to re-formulate the program such that each constraint is evaluated in isolation. Using the following rewrites, programs may be re-formulated to ensure conditional evaluation is only in terms of single conditions, making it simpler to evaluate.

x|y?a:b->x?a:(y?a:b)

x&y?a:b->x?(y?a:b):b

(x?a:b) op c->x?(a op c):(b op c)

a op (x?b:c)->x?(a op b):(a op c)

These rewrites can be used for rewriting complex conditions using nested muxes to simplify conditional evaluation and for moving muxes over arbitrary operators. For example, these rewrites can be applied until the consequences of the simplified conditions on each branch can be inferred.

At the branches, the union of (all of) the branch evaluations may be taken (under their respective conditions). In practice, intervals might not be sufficient, but the theory extends to unions of intervals naturally. This allows to accurately evaluate:

a≠b⇒a−b∈[−255, −1]∪[1,255]

Therefore, vectors of intervals may be used in the implementation.

Furthermore, constraints themselves can be re-written to further simplify the reasoning required. For example, a>b≡a−b>0≡0>b−a. By applying standard arithmetic rewrites and trying all reformulations of the conditions the reasoning about the implications becomes a simple syntactic check. If no relation is inferred, then a fall back to the weaker interval arithmetic may be performed.

Being able to automatically evaluate branching code facilitates deep automated optimizations and captures the human intuition behind case splitting optimizations. The motivation behind case-splitting in any hardware designs is that each branch can be optimized independently under the assumption that the branch is only taken if the condition is true/false. The proposed concept may enable automatically evaluating the consequences of branched designs and implementing branch specific optimizations. For example, this may allow to take the most naïve implementation of floating-point adder hardware and generate an optimized version based on these techniques.

In the following, some additional examples are given with respect to the proposed concept, providing a concept for automating constraint-aware datapath optimization using e-graphs.

RTL design requires engineers to exploit possible optimization opportunities in increasingly complex designs. In particular, floating-point hardware is the subject of intense scrutiny given its wide-ranging applications. These modules are almost always designed by hand. State-of-the-art electronic design automation (EDA) tools are currently unable to match human designs.

Combining program analysis and e(quivalence) graph rewriting techniques, the proposed concept exceeds the optimization capabilities of existing EDA tools for hardware design, with the ability to automatically exploit optimization opportunities generated by conditional branches in designs. In the following, the following topics will be discussed: expressibility of sub-domain equivalences in an e-graph to enable constraint-aware datapath optimization, a method and tool to automate the production of runtime branching/muxing conditions, leading to optimized hardware via constraint-aware optimization, a case study demonstrating the automated production of a highly-optimized floating-point subtractor, and an evaluation on benchmarks showing the generality of the method.

E-graphs are a data structure that represents equivalence classes (e-classes) of expressions compactly. Nodes in the e-graph represent functions or arguments which are grouped into e-classes. Directed edges connect a node to its child e-classes, representing the function's inputs. An e-graph is grown via the application of rewrites (e.g., x+0→x), which define equivalences over expressions. Constructive rewrite application means that the left-hand side remains in the data structure after application, avoiding the phase ordering problem. The e-graph grows monotonically, representing an increasing design space of equivalent implementations. An example e-graph before and after rewriting is presented in FIG. 1, which also shows how interval enclosures can be attached to each e-class from which useful properties can be learned. It is possible to learn such properties via abstract.

Compilers use program analysis to enable optimizations such as dead code elimination. Abstract interpretation is a theory used to over-approximate program properties. A weak but cheap to compute interpretation is interval arithmetic, which approximates variables by their input ranges and operators by their natural interval extension. Relational domains such as the polyhedral domain capture correlation and are more powerful but are more complex to compute.

On the datapath optimization problem, syntactic rewriting techniques have been explored, with one contribution using e-graphs. However, syntactic rewrites alone cannot express the deep transformations required for floating point hardware design. It will be shown that such transformations depend upon knowledge of intermediate values and domain restrictions under which the branches are executed.

Sub-Domain Equivalences: E-graphs represent expressions, drawn from a set Expr with variables evaluated over a domain [symbol] . A concrete semantics of expressions [symbol] ∈Expr→ [symbol] ⁿ→ [symbol] is considered, evaluating an expression as a function, e.g., [symbol] x+1 [symbol] is a function mapping values of the variable x to values of the expression x+1. This allows us to say that two expressions, eₐ and e_{b}, are congruent, eₐ≅e_{b}, iff [symbol] eₐ [symbol] = [symbol] e_{b} [symbol] .

This notion of congruence is strict and enforces equivalence across the entire domain [symbol] ⁿ. Under a weaker congruence relation, e.g., equivalence on a sub-domain, many additional congruences may hold. Expressions, eₐ and e_{b}, can be said to be congruent under c∈Expr iff

$$∀ v ∈ {𝒟}^{n} , c ( v ) ⇒ {e}_{a} ( v ) = {e}_{b} ( v )$$

$$i . e . , in every model where 〚 c 〛 holds , 〚 {e}_{a} 〛 = 〚 {e}_{b} 〛 .$$

$$This is denoted {e}_{a} {e}_{b} .$$

Input constraints or conditional branches can constrain the domain of operands for a given operator, potentially exposing additional optimization opportunities. The leading zero counter (LZC) circuit described in FIGS. 5a and 5b demonstrates how an input constraint can be exploited to build an equivalent but smaller and faster circuit. FIGS. 5a and 5b show an example of an e-graph before and after rewriting. The LZC node denotes a leading-zero counter. Edges are labelled with bit widths. The rewrite is valid due to the input constraint, x≥128, which implies that LZC(x+y)≤1, namely x+y has at most one leading zero.

Conditional branches initiated via an if statement in software or a mux in hardware are of particular interest in the present disclosure. As an example, the following C expressions are equivalent, even though f abs(x)≠x in general.

(x>0?f abs(x):0)≅(x>0?x:0)

Capturing these possibilities within datapath design optimization is useful. Sub-domain equivalence relations allow developers to optimize each branch of their code under different conditions, often resulting in better performance. This is the motivation behind introducing case splits into designs. Examples can be seen in the following sections.

Sub-Domains in E-Graphs: The preceding examples show the usefulness of capturing the set of possible variable values under which one cares about the correct evaluation of an expression, and to do so requires automated reasoning about the set of values an expression can take. Abstract interpretation is a well-known approach to this problem in the field of program analysis. In the following, the set of ‘care’ values of an expression are represented as a finite union of integer intervals, as this is sufficient to be able to reason about the industrial datapath designs being encountered. To be more precise, with each expression an element of the set A is associated:

$$𝒜 = \{ {{⋃}_{i = 1}}^{n} [ {a}_{i} , {b}_{i} \vert {a}_{i} \leq {b}_{i} , {a}_{i} , {b}_{i} ∈ ℤ , n ∈ ℕ ] \} .$$

For a given e∈Expr, A [symbol] e [symbol] ∈A can be computed, using interval arithmetic extended to unions of intervals incurring additional computational complexity. Following the technique in S. Coward, G. A. Constantinides, and T. Drane, “Combining E-Graphs with Abstract Interpretation,”, each e-class of expressions is associated with an element of A, which represents a conservative approximation of all evaluations of that e-class, as shown in FIGS. 5a and 5b. Such an approach is shown to produce a more accurate program analysis.

An additional operator, ASSUME, is introduced that is used to encode sub-domain equivalences. ASSUME takes two operands, an e-class containing equivalent Expr to evaluate and a set of e-classes containing Expr, encoding conditions that may be assumed to be true when evaluating the first argument. This effect is achieved by appending an additional special element to [symbol] , forming a new domain [symbol] ′=Z∪{*}.

Extending [symbol] notation to e-classes, the semantics under a single constraint are:

$$〚 ASSUME ( x , c ) 〛 = \{ \begin{matrix}〚 x 〛 & if 〚 c 〛 \\ * & else\end{matrix} . \qquad ( 1 )$$

Under multiple constraints, a * is returned if any of the conditions do not hold. The semantics of all other functions except the ternary operator ⋅?⋅:⋅ are extended to this new domain by also returning * iff at least one of their operands is *. The ternary operator receives special treatment as it returns a * only if the branching condition itself is a * or one of the reachable branches returns a *. In this way, * may precisely capture the code ‘failing an assertion’. The key benefit of this construction is that ≅_{c} can be defined in terms of congruence over the whole domain, that is

x≅_{c}y⇔ASSUME(x, c)≅ASSUME(y, c). (2)

Thus, reasoning may be performed automatically about sub-domain congruences using the e-graph machinery which applies for whole-domain congruences.

The consequences of the constraints are realized in the abstraction of ASSUME, if the assumed conditions constrain the expression under evaluation. The abstraction of ASSUME with a single constraint is:

$$𝒜 〚 ASSUME ( x , c ) 〛 = 𝒜 〚 x 〛 ⋂ I , \qquad ( 3 )$$

$$where$$

$$I = \{ \begin{matrix}( - ∞ , {c}^{′} ) & if [ x < {c}^{′} ] & ∈ c \\ ( {c}^{′} , ∞ ) & if [ x > {c}^{′} ] & ∈ c \\ [ {c}^{′} , {c}^{′} ] & if [ x == {c}^{′} ] & ∈ c \\ ( - ∞ , {c}^{′} ) ⋃ ( {c}^{′} , ∞ ) & if [ x \neq {c}^{′} ] & ∈ c \\ ( - ∞ , ∞ ) & else & \end{matrix} . \qquad ( 4 )$$

Since c is an e-class, it may include multiple equivalent Expr, therefore it can be tested whether any of the interpretable constraints are members of c. It is defined Constr⊆Expr, denoting the generalized set of constraints appearing on the right of the if statements in (4). An ASSUME with a set of constraints represents a further restriction of the domain via additional intersections. To demonstrate, suppose [symbol] A x=[−3, 3] [symbol] then,

A [symbol] ASSUME(x, x>0) [symbol] =[−3, 3]∩(0, ∞)=[1, 3].

Examples introduced later demonstrate how this theory enables additional optimizations. Experiments have shown that, when combined with the rewriting described in one of the following sections, it is only necessary to reason about the limited and computationally efficient set of constraints described later.

The theory described above was applied to an RTL optimization tool that is built on the egg e-graph library. Hardware designs were optimized at the RTL level of abstraction, operating on combinational logic on unsigned bit vectors. The tool parses input (System) Verilog using Yosys and sv2v, converting it into an e-graph with bitwidth annotations, following the approach in S. Coward, G. A. Constantinides, and T. Drane, “Automatic Datapath Optimization using E-Graphs”. A set of parameterized and generalized constraint-aware rewrites at the word level is developed for this work. For concision of notation, bitwidth annotations are not included when describing rewrites in the following. An online repository (https://figshare.com/s/e3ab2850662d24991cbc) summarizes rewrites described in the following. Rewrites are automatically applied to the e-graph for a number of iterations, then a delay optimized expression is extracted from which a System Verilog implementation is generated.

Bitwidth Reduction: In RTL, expressions are evaluated over unsigned bit-vectors, therefore arithmetic is computed with respect to some modulo. When propagating finite unions of integer intervals, a conservative approximation to modular intervals was used.

$$[ l , u ] mod p = \{ \begin{matrix}[ l mod p , u mod p ] & if ⌊ \frac{l}{p} ⌋ == ⌊ \frac{u}{p} ⌋ \\ [ 0 , p - 1 ] & else\end{matrix} . \qquad ( 5 )$$

By propagating finite unions of integer intervals throughout the e-graph, corresponding to each classes' possible outputs, bitwidth reduction is enabled. A bitwidth is maintained for each operand in the internal representation and are able to shrink this if it is discovered that the values which that operand can take would be representable in a smaller bitwidth. When combined with the ASSUME node abstraction described above and the rewrites described below, tighter approximations are generated throughout, meaning that bitwidths can be squeezed to their minimum required precision.

Enabling Sub-Domain Equivalences in E-Graphs: The ASSUME operator and its abstraction was introduced above. Focusing on RTL optimization, FIG. 6 describes rewrites to create, propagate and exploit ASSUMEs. FIG. 6 shows a table of ASSUME node rewrites, describing creation, propagation and simplifications. The op operator can represent any operator defined in the intermediate language.

The ASSUMEs will be induced by mux statements via the first rewrite in the table of FIG. 6. Recall that ASSUMEs allow to express multiple equivalence relations in the e-graph. Rewrites of the form ASSUME(x,c)→ASSUME(y,c) are used to encode x [symbol] y.

The usefulness of ASSUME nodes is illustrated via an example, a==0?a:−a, equivalent to, a==0?0:−a. Naively applying a→0, to the e-graph merges the nonequivalent expression, a==0?0:−0, into the e-graph. Using the table of FIG. 6 and the rewrite ASSUME (a, a==0)→ASSUME(0, a==0), an optimized expression is produced:

(a==0)?a:−a→(a==0)?ASSUME(a, a==0):ASSUME(−a,˜(a==0))→(a==0)?ASSUME(0, a==0):ASSUME(−a,˜(a==0))

By construction ASSUMEs can be treated as assignment statements in the implementation phase, meaning that they can be ignored in the optimized expression generated after rewriting. The remainder of the table of FIG. 6 is valuable in more complex scenarios. The second rewrite propagates ASSUME nodes down through the e-graph towards the inputs, essential because the constrained sub-expression may occur at any point in the tree (or not at all). The third combines nested ASSUME nodes by combining the two sets of conditions, which could be implemented as an AND of all the conditions. The final two rewrites prune unreachable branches. The validity of additional sub-domain rewrites is discovered by evaluating the abstractions of the ASSUME nodes and propagating this knowledge upwards through the e-graph.

Above, a C expression was discussed. In the following, a sequence of rewrites is shown to prove the desired equivalence.

(x>0)?f abs(x):0→(x>0)?ASSUME(f abs(x), x>0):ASSUME(0,˜(x>0))→(x>0)?f abs(ASSUME(x, x>0)):ASSUME(0,˜(x>0))→(x>0)?ASSUME(x, x>0):ASSUME(0,˜(x>0))

f abs(ASSUME(x, x>0))→ASSUME(x, x>0) is proven valid via equation (4), as [symbol] [symbol] ASSUME(x, x>0) [symbol] = [symbol] [symbol] x [symbol] ∩(0, ∞).

Condition Rewriting. Condition rewriting was described as a technique to mitigate the restrictions imposed by equation (4). Using the rewrites described in the table shown in FIG. 7, the tool attempts to transform c→c⁰, where c∈Expr and c⁰∈Constr. FIG. 7 shows a table of condition rewrites, used to transform members of Expr into members of Constr.

Considering an e-graph containing ASSUME(a−b, a>b). a>b∉Constr⇒ [symbol] [symbol] ASSUME(a−b, a>b) [symbol] = [symbol] [symbol] a−b [symbol] . By rewriting a>b→Ja−b>0, a−b>0K∈Constr is merged into the constraint e-class, triggering a refinement via equation (4),

[symbol]

[symbol]

ASSUME(a−b, a−b>0) [symbol] = [symbol] [symbol] a−b [symbol] ∩(0, ∞).

An e-class can contain many equivalent representations of a constraint so there is no need to find the single ideal representation. At the same time, the tool is also rewriting the expression under evaluation for optimization purposes. But a side benefit is that it may also discover how the particular imposed constraint impacts the expression.

In RTL design conjunctions or disjunctions of conditions are often discounted. Logical and/or are handled via mux rewrites.

(a∧b)?c:d→a?(b?c:d):d (6)

(a∨b)?c:d→a?c:(b?c:d) (7)

These rewrites break conjunctions and disjunctions into simpler Expr that the tool can reason about. Rewriting mux operations further mitigates the restrictions imposed by equation (4).

Delay Modeling: The final e-graph contains many functionally equivalent implementations of the input RTL. In the following, maximal performance is targeted and the design with the shortest critical path delay is extracted. If multiple designs achieve identical delay, the smallest area circuit amongst them is extracted.

A similar approach to previous work (E. Ustun, I. San, J. Yin, C. Yu, and Z. Zhang, “IMpress: Large Integer Multiplication Expression Rewriting for FPGA HLS”) on multiplier design for FPGAs using e-graphs is taken and a theoretical model of delay is calculated. For each operator, an estimate is calculated based on a fixed component architecture for the total number of two-input gates on the operator's critical path as a function of operator precision. At each operator the total delay to the output is the maximum delay across all its children plus its own delay. Using a theoretical model enables efficient design space exploration and avoids long logic synthesis runtimes.

The best design is extracted from the e-graph using egg's standard extraction algorithm combined with a delay/area weighted sum objective function. For a performance prioritized optimization, common sub-expressions are not a significant factor, therefore an integer linear programming approach to extraction was not used.

CASE STUDY: FLOATING-POINT SUBTRACT: To demonstrate the capabilities of such an approach, the tool was used to automatically optimize a hardware implementation of a floating-point subtractor. These subtractors are amongst the most well studied hardware components and are the target of deep optimization efforts. Specifically, it will be demonstrated how the tool is able to optimize a half-precision floating-point subtractor, that computes 2^{ea}×1.ma−2^{eb}×1.mb, producing a half-precision floating-point output. The focus is on the subtraction case because it is well-known to be harder due to the potential for cancellation. For simplicity, the case is considered where the output is rounded towards zero. Exception handling and denormal, NaN and infinite inputs are ignored.

The input design in FIG. 4a, is a naive, easy to write, implementation of the mantissa calculation for floating-point subtraction. In the naive design, the mantissas are concatenated with preceding zeros to ensure that after the alignment, all bits are retained. This results in a 42-bit subtractor, the result of which is normalized, using an LZC and a right shift. Discarding the leading one from this result, the output mantissa is then the 10 most significant remaining bits.

The most well-known floating-point subtract optimization known as the near-path/far-path optimization, stems from the observation that the critical path is never fully exercised. It splits the design into two paths. The near path is taken when |ea−eb|<2, requiring only a small alignment shift. The far path is taken when |ea−eb|>1. On this path catastrophic cancellation cannot occur, simplifying the renormalization logic. FIGS. 5a and 5b shows a related optimization.

The tool parses the RTL corresponding to FIG. 4a and generates an initial e-graph. Typically, LZCs are expressed in Verilog as case statements. To enable operator specific rewrites, an LZC operator is included in the intermediate language, with accompanying rewrites to map appropriate case statements to this operator.

Once the tool has mapped the input design to its intermediate language optimization begins. Firstly, the tool introduces the case split into the e-graph via a rewrite, which is intended to possibly isolate catastrophic cancellation to a single branch.

a−(b>>c)→(c>1)?a−(b>>c):a−(b>>c)

Note that this inserts a mux directly after the subtraction, which may be beneficial in some instances, but in this case using mux propagation rewrites, the tool pushes the mux towards the output.

a op (b?c:d)→b?a op c:a op d

This duplicates operations, leaving a mux at the output between two identical branches. Using the rewrites from the table of FIG. 6, the tool creates and propagates ASSUMEs down each branch and after several rewriting iterations, the following are created.

ASSUME(Exp Diff, Exp Diff>1) (8)

ASSUME(Exp Diff,˜(Exp Diff>1)) (9)

Computing the abstraction of equation (8), equation (4) takes effect immediately. For equation (9), two sequential condition rewrites transform it into an equivalent Constr, Exp Diff<2. These constrained value ranges are propagated along each branch triggering a chain of branch specific rewrites and bitwidth reductions.

After 11 iterations of rewriting an e-graph of approximately 40,000 nodes and 14,000 classes is grown. The optimized design shown in FIG. 4b is extracted from this e-graph, within a total runtime of 22 minutes, the majority of which is spent growing the e-graph. Note that the two branches are reduced to distinct implementations as a result of the constraint-aware rewrites. Further optimizations apply to even this design, but these are often gate level optimizations, a level of optimization that is left to the logic synthesis tools.

The input and optimized RTLs are proven equivalent using the Synopsys Datapath Validation (DPV) tool, a formal equivalence checking tool that runs in minutes on this problem. Both designs were synthesized at a range of delay targets using Synopsys Fusion Compiler for a TSMC 7 nm cell library. The results are shown in FIG. 8. The optimized design can achieve a 33% lower delay in a circuit area 41% smaller than the behavioral architecture.

To demonstrate that the results are not hand-tuned to the case study, this section uses the tool to optimize several different designs. The tool was run for six iterations on smaller test cases generating e-graphs of less than 150 nodes, running in under 0.25 seconds. It was shown that the tool can automatically do dead code elimination and generalize optimizations learnt from the floating-point case study. The behavioral and optimized RTLs are proven equivalent using the DPV tool. The competing RTLs are synthesized using Fusion Compiler at the minimum delay target that each implementation can meet. The table of FIG. 9 summarizes the results. FIG. 9 shows a table of logic synthesis results using the Fusion compiler for circuit delay (ns) and circuit area (μm²). Each implementation is synthesized at the minimum delay target it can achieve.

The float to unorm design converts a half-precision float (less than or equal to 1 in magnitude) to a unorm11, rounding down, as described in the DirectX specifications. The tool reuses the round-off based optimizations described above. The interpolation example is a kernel from an Intel® media module, computing an interpolation between four pixels and clamping the output. For certain clamping thresholds, the tool automatically detects that the threshold can never be met and optimizes the clamping away.

c ? a : b→b if [symbol] [symbol] c [symbol] ==[0, 0]

This test case relies on rewriting to obtain tight approximations to the range of outputs and only with this rewriting can the tool prove that the clamping is unnecessary. Namely, naive interval arithmetic would not suffice.

The unorm to float design special cases zero inputs, such that they are handled on a separate path. The tool automatically propagates the domain restriction and applies the constraint-aware optimizations generating a smaller circuit that matches the behavioural's performance. In this example the interplay of rewriting and program analysis is invaluable.

The present disclosure combines e-graphs with constraint-aware program analysis to automate RTL optimization exceeding the capabilities of existing EDA tools. By representing multiple equivalence relations in an e-graph, branch specific optimizations are exploited and tight approximations are computed to intermediate signals using an extension of interval arithmetic. These techniques enable bitwidth reduction, dead code elimination and automated case splitting. The optimization of a floating-point subtraction unit was automatized, recreating efficient human implementations and saving 41% of area and 33% of delay.

In other test cases the tool reduced circuit area by up to 48% with minimal delay penalty demonstrating its generalizability. The delay model may be refined by considering a bit-level delay model. Multi-objective optimization may be explored to generate Pareto curves of designs. Having matched human designers on floating-point unit design, the tool may be used to discover novel architectures in the near future. Interactive tool usage may be used by designers to propose case-splits based on their intuition and have the tool automatically optimize the proposed design.

More details and aspects of the concept for automating constraint-aware datapath optimization using e-graphs are mentioned in connection with the proposed concept or one or more examples described above or below (e.g., FIG. 1a to 4b). The concept for automating constraint-aware datapath optimization using e-graphs may comprise one or more additional optional features corresponding to one or more aspects of the proposed concept or one or more examples described above or below.

In the following, a background is given on graph-based representations of circuits, which is related to the condition-based optimization techniques introduced above. This aspect of the present disclosure relates to a concept for improving or optimizing a circuit design in digital hardware design. In digital hardware design, hardware description languages, such as Verilog or VHDL, are often used to define the functionality of a circuit. While such hardware description languages are powerful tools for specifying the functionality of a circuit on the register transfer level (and above), they allow the definition of a circuit design without taking into account hardware structures, such as custom-designed hardware blocks, which would allow to improve the implementation cost or processing delay caused by the respective circuit design. While logic synthesis tools are often equipped to provide some level of improvement or optimization, such tools are often limited to a narrow design space. Manual improvements may be used to overcome this limitation, at the cost of additional manual effort and the risk of introducing bugs in edge cases.

This aspect of the proposed concept may provide additional improvements to circuit designs, e.g., by generating an improved RTL representation of a circuit that is logically equivalent to an initial (RTL) representation of the circuit, albeit with advantageous properties. In the following, the terms “improved” and “optimized” are used interchangeably. The term “optimized”, or “optimization” does not necessarily imply that the result of the process is the optimal version. In the present concept, the term “optimized” indicates that some thing (i.e., the circuit design) is superior to the initial version of the thing (i.e., the circuit design).

The process starts, both in the graph-based optimization technique of this aspect and in the condition-based optimization technique introduced above, with generating the graph representation of the circuit. This can occur from any source, e.g., from a higher-abstraction level representation of the circuit such as SystemVerilog, or from another RTL representation of the circuit, e.g., as defined in the Verilog or VHDL hardware description language. In other words, the processing circuitry may be configured to generate the graph representation from a further RTL representation of the circuit. Thus, the proposed concept may be used to improve or optimize an existing RTL representation of the circuit.

In general, the graph representation of the circuit may model a data flow between the components of the circuits, i.e., the graph representation may be a data-flow graph representing the circuit. The graph representation comprises two types of vertices (i.e., nodes)—vertices of the first set of vertices that represent operators, and vertices of the second set of vertices that represent operands. The vertices representing the operands are connected to the vertices representing the operators via the edges of the graph structures. Moreover, vertices representing operators may be connected to other vertices representing operators as well, with the result of an operation performed by an operator being used as operand by the other operator. Thus, the output of an operation performed by an operator may be provided as operand to another operator, or as an output of the circuit.

For example, the edges between the vertices may comprise labels, such as 0[p] or 1[q]. These edge labels indicate the bit-width of the respective operator, with the “0” or “1” part indicating that the operand (or result of an operation performed by an operator) is used as 0^{th}, 1^{st} etc. operand, and the [p] or [q] part indicating the bit-width of the respective operand. In other words, the processing circuitry may be configured to include a bit-width of the operands in the graph representation as edge labels of the edges between the vertices representing the operands (or the vertices representing operators that provide an operand) and the vertices representing the operators accessing the operands. These edge labels may later be used to determine logical equivalence between operators, with some operators only available, or efficient, for a sub-set of the supported bit-widths. The bit-widths being used may change if the proposed concept is applied to parametrizable circuit designs, i.e., circuit designs that can be adapted according to a parameter, with the parameter specifying, explicitly or implicitly, the bit-width.

In this aspect of the proposed concept, the graph representation is extended by adding logically equivalent operators to the graph. These logically equivalent operators are added as alternatives to the operators already present in the graphs. Such a dense representation of equivalent graphs, and thus designs, by using a so-called equivalence graph to build the graph representation. Accordingly, the graph representation may be based on an equivalence graph. An equivalence graph is a graph that comprise multiple equivalent representations of at least a sub-graph of the graph.

To enrich the graph with the logically equivalent operators, the one or more logically equivalent operators are determined for the one or more operators represented by the one or more vertices of the first set of vertices of the graph. This may be done based on a set of rewrites. In other words, the processing circuitry may be configured to determine the one or more logically equivalent operators based on a pre-defined set of logically equivalent transformations (i.e., the rewrites) between operators.

There are various types of possible logically equivalent transformations. Some logically equivalent transformations are derived from bit vector arithmetic. For example, the pre-defined set of logically equivalent transformation may comprise one or more transformations that are based on bit vector arithmetic, e.g., at least one of a transformation related to commutativity, a transformation related to multiplication associativity, a transformation related to addition associativity, a transformation related to distributing a multiplication over multiple additions, a transformation related to a sum of multiple instances of the same operand, a transformation related to a sum of multiple instances of the same operand, with one instance of the operand being part of a multiplication, a transformation related to an addition of zero, a transformation between a subtraction and an addition of a negation, a transformation related to a multiplication by one, and a transformation related to a multiplication by two. Some logically equivalent transformations may be derived from bit vector identity. For example, the pre-defined set of logically equivalent transformation may comprise one or more transformations that are based on bit vector identity, e.g., at least one of a transformation related to a merging of two left shift or two right shift operations, a transformation related to eliminating a redundant selection, a transformation between a negative value and an inverse, a transformation between an inverse and a negative value, and a transformation related to an inversion of a multiplication.

Some logically equivalent transformations may be derived from constant expansion. For example, the pre-defined set of logically equivalent transformation may comprise one or more transformations that are based on constant expansion, e.g., at least one of a transformation related to a multiplication by a constant, and a transformation related to an expansion of a multiplication of an operand by one to a multiplication of an operand by two.

Some logically equivalent transformations may be derived from arithmetic logic exchange. For example, the pre-defined set of logically equivalent transformation may comprise one or more transformations that are based on arithmetic logic exchange, e.g., at least one of a transformation related to a left or right shift applied to an addition, a transformation related to a left shift applied to a multiplication, a transformation related to expanding a selection comprising an addition, a transformation related to expanding a selection by inserting zero, a transformation related to expanding a selection by moving zero, and a transformation between a concatenation and an addition. Such exchanges may be used to substitute operators, e.g., such that an operator is replaced by another (or a group of other) operator(s). For example, the pre-defined set of logically equivalent transformations between operators may comprise at least one transformation for transforming two or more operators into two or more different operators. For example, the pre-defined set of logically equivalent transformations between operators may comprises at least one transformation for transforming a combination of a first operator and a first operand into a combination of a second operator and a second operand, with the first operator being different from the second operator and the first operand being different from the second operand. For example, a multiplication by 2ⁿ may be performed by performing a bit shift. Accordingly, the second operator may be a shift operator.

Some logically equivalent transformations may be derived from merging operators. For example, the pre-defined set of logically equivalent transformation may comprise one or more transformations that are based on merging operators, e.g., at least one of a transformation related to merging additions using a summation operator, a transformation related to multiplexing arrays, and a transformation related to a fused multiply add (FMA). These transformations are directed at merging multiple operators, e.g., by transforming multiple additions into a single summation or by using a multiplex array operation instead of two multiplications of an operand and of its inverse. Accordingly, the pre-defined set of logically equivalent transformations between operators may comprise at least one transformation for transforming two or more operators into a single operator. For example, the single operator may be one of a merge summation operator, a multiplex array operator and a fused-multiply-add operator.

Not every transformation is suitable for every bit-width. For example, some specialized operators exist with support for a limited set of bit-widths. As a consequence, the logical equivalence of the one or more logically equivalent operators may depend on the bit-width of the operands being accessed by the one or more operators. Transformations that involve such operators may thus be limited to these bit-widths (or suffer inefficiencies that occur due to additional operators required for expanding the bit-widths). Accordingly, the processing circuitry is configured to determine the one or more logically equivalent operators based on the bit-width of the operands. Moreover, not every transformation is suitable for any content of an operand. These conditions may be considered to be sufficient for safely rewriting the operators, but not necessary in all cases. For example, if these conditions hold, the rewrites can be applied correctly. However, in some cases, the conditions do not hold, and the rewrites can still be applied correctly.

Once the once or more logically equivalent operators are determined, they are inserted into the graph representation, with the result of the graph representation comprising the plurality of logically equivalent representations of the circuit. These logically equivalent representations may be extracted from the graph representation, e.g., by selecting one of the logically equivalent operators wherever logically equivalent operators are included in the graph representation.

However, not every representation may be equally favorable. For example, some representations may be more costly to manufacture as they require more silicon area. Some representations may have an increased power draw (also due to more silicon area or due to silicon structures that increase the power consumption). Some representations may yield a longer processing delay (when many operators have to be used in succession), limiting the maximal frequency of the circuit. Therefore, one of the representations may be selected that has desired properties with respect to aspects such as silicon area, power draw and processing delay. The processing circuitry may be configured to select one representation from the plurality of logically equivalent representations of the circuit based on a selection criterion, and to generate the RTL representation based on the selected representation. As outlined above, one possible selection criterion is the implementation cost (e.g., in terms of silicon area or power consumption). Accordingly, the representation may be selected based on an implementation cost of the representation. For example, the implementation cost may be based on at least one of a silicon area (or more general semiconductor area) required by the representation and a power consumption of the representation. Another possible criterion is the processing delay, i.e., how much time the circuit takes to provide its output based on the input. Accordingly, the representation may be selected based on a processing delay of the representation. The processing circuitry may be configured to determine the value underlying the selection criterion for the plurality of logically equivalent representations, i.e., of the implementation cost and/or processing delay, e.g., based on a database or data structure comprising information on the implementation cost and/or processing delay of the operators, and to select the representation based on a comparison of the determined values.

The RTL representation of the circuit is then generated based on one of the plurality of equivalent representations of the circuit, e.g., based on the selected representation. For example, the RTL representation may be derived from the graph representation, by using the operators and operands included in the representation.

As outlined above, in some cases, circuit designs may be parametrized, with the same general design being used for different bit-widths. However, such designs are often sub-optimal for some of the supported bit-widths and may thus be improved using the proposed concept. For example, depending on the parameter, and thus bit-width chosen, different representations may be desirable. The selection of the representation may thus depend on the bit-width being used by the specific instance of the circuit. Accordingly, the processing circuitry may be configured to select one representation from the plurality of logically equivalent representations of the circuit based on a selection criterion, with the selection criterion being dependent on the bit-width of the operands, and to generate the RTL representation based on the selected representation. For example, the implementation cost (semiconductor area and/or power consumption) and processing delay of a representation may differ for different bit-widths. Consequently, the representation may be selected based on at least one of an implementation cost and a processing delay of the representation, with the implementation cost and/or processing delay being based on the bit-width of the operands. For some bit-widths, a first representation may be advantageous according to the selection criterion, and for some other bit-widths a second representation may be advantageous according to the selection criterion.

This can be leveraged to generate multiple designs, with each design being advantageous for a parameter or range of parameters (and thus bit-width or range of bit-widths). The processing circuitry may be configured to select, for each of a plurality of pre-defined bit-widths of the operands, one representation from the plurality of logically equivalent representations of the circuit based on the selection criterion, and to generate an RTL representation for each pre-defined bit-width based on the respective selected representation. For some bit-widths, the same representation (architecture) may be deemed to be advantageous according to the selection criterion, and thus selected. Accordingly, a separate RTL representation may be generated for each unique and/or non-duplicate representation selected. In some examples, a separate RTL representation may be generated for each pre-defined bit-width. For example, the respective RTL representation may be based on the respective bit-width, e.g., by hard-coding the bit-width as part of the RTL representation.

For example, the processing circuitry may be configured to output the generated RTL representation or representations, e.g., via a computer-readable medium or via a signal comprising the respective RTL representation or representations.

In the following, some examples of the proposed concept are presented:

An example (e.g., example 1) relates to an apparatus (10) for generating a register transfer level (RTL) representation of a circuit, the apparatus (10) comprising interface circuitry (12), machine-readable instructions and processing circuitry (14) to execute the machine-readable instructions to generate a graph representation of the circuit, the graph representation comprising a first set of vertices representing operators and a second set of vertices representing operands of the graph representation of the circuit, identify one or more conditional operators, with each conditional operator defining at least two possible outcomes depending on the condition, and with each possible outcome being represented by a branch of the graph representation of the circuit, determine, for the possible outcomes of the one or more conditional operators, a condition imposed by the respective outcome, annotate at least a subset of the vertices of the respective branches representing the possible outcomes with the condition imposed by the corresponding outcome, and generate an RTL representation of the circuit based on the graph representation of the circuit.

Another example (e.g., example 2) relates to a previous example (e.g., example 1) or to any other example, further comprising that the processing circuitry is to execute the machine-readable instructions to insert, for the identified conditional operators, the branches representing the possible outcomes of the one or more conditional operators.

Another example (e.g., example 3) relates to a previous example (e.g., one of the examples 1 or 2) or to any other example, further comprising that the processing circuitry is to execute the machine-readable instructions to evaluate, for the branches representing the possible outcomes, an aggregate condition based on one or more conditions the vertices of the respective branches are annotated with, and to determine, for at least the vertices representing conditional operators, a union of the aggregate conditions evaluated for the branches representing the possible outcomes connected to the vertex representing the respective conditional operator.

Another example (e.g., example 4) relates to a previous example (e.g., example 3) or to any other example, further comprising that the condition imposed by the respective conditional operator is related to interval arithmetic, wherein the processing circuitry is to execute the machine-readable instructions to evaluate, for the branches representing the possible outcomes, one or more constrained value intervals for one or more of the operands based on one or more conditions the vertices of the respective branches are annotated with, and to determine, for at least the vertices representing conditional operators, a union of the constrained value intervals evaluated for the branches representing the possible outcomes connected to the vertex representing the respective conditional operator.

Another example (e.g., example 5) relates to a previous example (e.g., one of the examples 1 to 4) or to any other example, further comprising that the processing circuitry is to execute the machine-readable instructions to propagate the conditions imposed by the respective outcomes through the graph.

Another example (e.g., example 6) relates to a previous example (e.g., one of the examples 1 to 5) or to any other example, further comprising that the processing circuitry is to execute the machine-readable instructions to apply at least one optimization algorithm on the respective branches representing the possible outcomes, with the optimization algorithm being based on the condition imposed by the corresponding outcome.

Another example (e.g., example 7) relates to a previous example (e.g., example 6) or to any other example, further comprising that a condition-dependent branch-specific optimization is applied on the respective branches.

Another example (e.g., example 8) relates to a previous example (e.g., one of the examples 1 to 7) or to any other example, further comprising that the processing circuitry is to execute the machine-readable instructions to detect at least one dead branch within the graph-based representation based on the condition or conditions the vertices of the branch are annotated with.

Another example (e.g., example 9) relates to a previous example (e.g., one of the examples 1 to 8) or to any other example, further comprising that the respective branches representing the possible outcomes are data paths.

Another example (e.g., example 10) relates to a previous example (e.g., one of the examples 1 to 9) or to any other example, further comprising that the processing circuitry is to execute the machine-readable instructions to annotate at least the subset of the vertices of the respective branches representing the possible outcomes with the condition imposed by the corresponding outcome by inserting a third set of vertices representing the conditions into the graph and inserting edges between the vertices being annotated and the vertices representing the respective conditions.

Another example (e.g., example 11) relates to a previous example (e.g., one of the examples 1 to 10) or to any other example, further comprising that the graph representation is a data-flow graph representing the circuit.

Another example (e.g., example 12) relates to a previous example (e.g., one of the examples 1 to 11) or to any other example, further comprising that the graph representation is based on an equivalence graph.

Another example (e.g., example 13) relates to a previous example (e.g., one of the examples 1 to 12) or to any other example, further comprising that the processing circuitry is to execute the machine-readable instructions to generate the graph representation from a further RTL representation of the circuit.

Another example (e.g., example 14) relates to a previous example (e.g., one of the examples 1 to 13) or to any other example, further comprising that the processing circuitry is to execute the machine-readable instructions to determine, for one or more operators represented by the one or more vertices of the first set of vertices of the graph, one or more logically equivalent operators, include the one or more logically equivalent operators in the graph representation, such that the graph representation comprises a plurality of logically equivalent representations of the circuit, and generate the RTL representation of the circuit based on one of the plurality of equivalent representations of the circuit.

Another example (e.g., example 15) relates to a previous example (e.g., example 14) or to any other example, further comprising that the processing circuitry is to execute the machine-readable instructions to determine the respective one or more logically equivalent operators based on at least one condition the vertex of the respective operator is annotated with and/or based on at least one condition a vertex inside a branch connected to the vertex of the respective operator is annotated with.

Another example (e.g., example 16) relates to a previous example (e.g., one of the examples 14 or 15) or to any other example, further comprising that the processing circuitry is to execute the machine-readable instructions to select one representation from the plurality of logically equivalent representations of the circuit based on a selection criterion, and to generate the RTL representation based on the selected representation.

Another example (e.g., example 17) relates to a previous example (e.g., example 16) or to any other example, further comprising that the selection criterion is based on at least one of an implementation cost of the representation, a silicon area required by the representation, a power consumption of the representation and on a processing delay of the representation.

Another example (e.g., example 18) relates to a previous example (e.g., one of the examples 14 to 17) or to any other example, further comprising that the processing circuitry is to execute the machine-readable instructions to determine the one or more logically equivalent operators based on a pre-defined set of logically equivalent transformations between operators.

Another example (e.g., example 19) relates to a previous example (e.g., one of the examples 14 to 18) or to any other example, further comprising that the processing circuitry is to execute the machine-readable instructions to include a bit-width of the operands in the graph representation as edge labels of the edges between the vertices representing the operands and the vertices representing the operators accessing the operands.

An example (e.g., example 20) relates to an apparatus (10) for generating a register transfer level (RTL) representation of a circuit, the apparatus (10) comprising processing circuitry (14) configured to generate a graph representation of the circuit, the graph representation comprising a first set of vertices representing operators and a second set of vertices representing operands of the graph representation of the circuit, identify one or more conditional operators, with each conditional operator defining at least two possible outcomes depending on the condition, and with each possible outcome being represented by a branch of the graph representation of the circuit, determine, for the possible outcomes of the one or more conditional operators, a condition imposed by the respective outcome, annotate at least a subset of the vertices of the respective branches representing the possible outcomes with the condition imposed by the corresponding outcome, and generate an RTL representation of the circuit based on the graph representation of the circuit.

An example (e.g., example 21) relates to a device (10) for generating a register transfer level (RTL) representation of a circuit, the device comprising means for processing (10) for generating a graph representation of the circuit, the graph representation comprising a first set of vertices representing operators and a second set of vertices representing operands of the graph representation of the circuit, identifying one or more conditional operators, with each conditional operator defining at least two possible outcomes depending on the condition, and with each possible outcome being represented by a branch of the graph representation of the circuit, determining, for the possible outcomes of the one or more conditional operators, a condition imposed by the respective outcome, annotating at least a subset of the vertices of the respective branches representing the possible outcomes with the condition imposed by the corresponding outcome, and generating an RTL representation of the circuit based on the graph representation of the circuit.

An example (e.g., example 22) relates to a method for generating a register transfer level (RTL) representation of a circuit, the method comprising generating (110) a graph representation of the circuit, the graph representation comprising a first set of vertices representing operators and a second set of vertices representing operands of the graph representation of the circuit, identifying (120) one or more conditional operators, with each conditional operator defining at least two possible outcomes depending on the condition, and with each possible outcome being represented by a branch of the graph representation of the circuit, determining (140), for the possible outcomes of the one or more conditional operators, a condition imposed by the respective outcome, annotating (150 ) at least a subset of the vertices of the respective branches representing the possible outcomes with the condition imposed by the corresponding outcome, and generating (190) an RTL representation of the circuit based on the graph representation of the circuit.

Another example (e.g., example 23) relates to a previous example (e.g., example 22) or to any other example, further comprising that the method comprises inserting (130), for the identified conditional operators, the branches representing the possible outcomes of the one or more conditional operators.

Another example (e.g., example 24) relates to a previous example (e.g., one of the examples 22 or 23) or to any other example, further comprising that the method comprises evaluating (160), for the branches representing the possible outcomes, an aggregate condition based on one or more conditions the vertices of the respective branches are annotated with, and determining (165), for at least the vertices representing conditional operators, a union of the aggregate conditions evaluated for the branches representing the possible outcomes connected to the vertex representing the respective conditional operator.

Another example (e.g., example 25) relates to a previous example (e.g., example 24) or to any other example, further comprising that the condition imposed by the respective conditional operator is related to interval arithmetic, wherein the method comprises evaluating, for the branches representing the possible outcomes, one or more constrained value intervals for one or more of the operands based on one or more conditions the vertices of the respective branches are annotated with, and determining, for at least the vertices representing conditional operators, a union of the constrained value intervals evaluated for the branches representing the possible outcomes connected to the vertex representing the respective conditional operator.

Another example (e.g., example 26) relates to a previous example (e.g., one of the examples 22 to 25) or to any other example, further comprising that the method comprises propagating (145) the conditions imposed by the respective outcomes through the graph.

Another example (e.g., example 27) relates to a previous example (e.g., one of the examples 22 to 26) or to any other example, further comprising that the method comprises applying (170) at least one optimization algorithm on the respective branches representing the possible outcomes, with the optimization algorithm being based on the condition imposed by the corresponding outcome.

Another example (e.g., example 28) relates to a previous example (e.g., example 27) or to any other example, further comprising that a condition-dependent branch-specific optimization is applied on the respective branches.

Another example (e.g., example 29) relates to a previous example (e.g., one of the examples 22 to 28) or to any other example, further comprising that the method comprises detecting (175) at least one dead branch within the graph-based representation based on the condition or conditions the vertices of the branch are annotated with.

Another example (e.g., example 30) relates to a previous example (e.g., one of the examples 22 to 29) or to any other example, further comprising that the respective branches representing the possible outcomes are data paths.

Another example (e.g., example 31) relates to a previous example (e.g., one of the examples 22 to 30) or to any other example, further comprising that the method comprises annotating (150) at least the subset of the vertices of the respective branches representing the possible outcomes with the condition imposed by the corresponding outcome by inserting a third set of vertices representing the conditions into the graph and inserting edges between the vertices being annotated and the vertices representing the respective conditions.

Another example (e.g., example 32) relates to a previous example (e.g., one of the examples 22 to 31) or to any other example, further comprising that the graph representation is a data-flow graph representing the circuit.

Another example (e.g., example 33) relates to a previous example (e.g., one of the examples 22 to 32) or to any other example, further comprising that the graph representation is based on an equivalence graph.

Another example (e.g., example 34) relates to a previous example (e.g., one of the examples 22 to 33) or to any other example, further comprising that the method comprises generating (110) the graph representation from a further RTL representation of the circuit.

Another example (e.g., example 35) relates to a previous example (e.g., one of the examples 22 to 34) or to any other example, further comprising that the method comprises determining (180), for one or more operators represented by the one or more vertices of the first set of vertices of the graph, one or more logically equivalent operators, including (182) the one or more logically equivalent operators in the graph representation, such that the graph representation comprises a plurality of logically equivalent representations of the circuit, and generating the RTL representation of the circuit based on one of the plurality of equivalent representations of the circuit.

Another example (e.g., example 36) relates to a previous example (e.g., example 35) or to any other example, further comprising that the method comprises determining (180) the respective one or more logically equivalent operators based on at least one condition the vertex of the respective operator is annotated with and/or based on at least one condition a vertex inside a branch connected to the vertex of the respective operator is annotated with.

Another example (e.g., example 37) relates to a previous example (e.g., one of the examples 35 or 36) or to any other example, further comprising that the method comprises selecting (184) one representation from the plurality of logically equivalent representations of the circuit based on a selection criterion and generating the RTL representation based on the selected representation.

Another example (e.g., example 38) relates to a previous example (e.g., example 37) or to any other example, further comprising that the selection criterion is based on at least one of an implementation cost of the representation, a silicon area required by the representation, a power consumption of the representation and on a processing delay of the representation.

Another example (e.g., example 39) relates to a previous example (e.g., one of the examples 35 to 38) or to any other example, further comprising that the method comprises determining (180) the one or more logically equivalent operators based on a pre-defined set of logically equivalent transformations between operators.

Another example (e.g., example 40) relates to a previous example (e.g., one of the examples 35 to 39) or to any other example, further comprising that the method comprises including a bit-width of the operands in the graph representation as edge labels of the edges between the vertices representing the operands and the vertices representing the operators accessing the operands.

Another example (e.g., example 41) relates to a computer system comprising the apparatus or device according to one of the examples 1 to 21 (or according to any other example) or being configured to perform the method of one of the examples 22 to 40 (or according to any other example).

Another example (e.g., example 42) relates to a non-transitory, computer-readable medium comprising a program code that, when the program code is executed on a processor, a computer, or a programmable hardware component, causes the processor, computer, or programmable hardware component to perform the method of one of the examples 22 to 40 (or according to any other example).

Another example (e.g., example 43) relates to a non-transitory machine-readable storage medium including program code, when executed, to cause a machine to perform the method of one of the examples 22 to 40 (or according to any other example).

Another example (e.g., example 44) relates to a computer program having a program code for performing the method of one of the examples 22 to 40 (or according to any other example) when the computer program is executed on a computer, a processor, or a programmable hardware component.

Another example (e.g., example 45) relates to a machine-readable storage including machine readable instructions, when executed, to implement a method or realize an apparatus as claimed in any pending claim.

An example (e.g., example 46) relates to a method, apparatus, device, or computer program according to any one of the examples described herein.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

As used herein, the term “module” refers to logic that may be implemented in a hardware component or device, software or firmware running on a processing unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processing units, state machine circuitry, and/or firmware that stores instructions executable by programmable circuitry. Modules described herein may, collectively or individually, be embodied as circuitry that forms a part of a computing system. Thus, any of the modules can be implemented as circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processing units capable of executing computer-executable instructions to perform any of the disclosed methods. As used herein, the term “computer” refers to any computing system or device described or mentioned herein. Thus, the term “computer-executable instruction” refers to instructions that can be executed by any computing system or device described or mentioned herein.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based examples (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

The disclosed methods, apparatuses, and systems are not to be construed as limiting in any way. Instead, the present disclosure is directed toward all novel and nonobvious features and aspects of the various disclosed examples, alone and in various combinations and subcombinations with one another. The disclosed methods, apparatuses, and systems are not limited to any specific aspect or feature or combination thereof, nor do the disclosed examples require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. An apparatus for generating a register transfer level (RTL) representation of a circuit, the apparatus comprising interface circuitry, machine-readable instructions and processing circuitry to execute the machine-readable instructions to:
generate a graph representation of the circuit, the graph representation comprising a first set of vertices representing operators and a second set of vertices representing operands of the graph representation of the circuit;
identify one or more conditional operators, with each conditional operator defining at least two possible outcomes depending on the condition, and with each possible outcome being represented by a branch of the graph representation of the circuit;
determine, for the possible outcomes of the one or more conditional operators, a condition imposed by the respective outcome;
annotate at least a subset of the vertices of the respective branches representing the possible outcomes with the condition imposed by the corresponding outcome; and
generate an RTL representation of the circuit based on the graph representation of the circuit.

2. The apparatus according to claim 1, wherein the processing circuitry is to execute the machine-readable instructions to insert, for the identified conditional operators, the branches representing the possible outcomes of the one or more conditional operators.

3. The apparatus according to claim 1, wherein the processing circuitry is to execute the machine-readable instructions to evaluate, for the branches representing the possible outcomes, an aggregate condition based on one or more conditions the vertices of the respective branches are annotated with, and to determine, for at least the vertices representing conditional operators, a union of the aggregate conditions evaluated for the branches representing the possible outcomes connected to the vertex representing the respective conditional operator.

4. The apparatus according to claim 3, wherein the condition imposed by the respective conditional operator is related to interval arithmetic, wherein the processing circuitry is to execute the machine-readable instructions to evaluate, for the branches representing the possible outcomes, one or more constrained value intervals for one or more of the operands based on one or more conditions the vertices of the respective branches are annotated with, and to determine, for at least the vertices representing conditional operators, a union of the constrained value intervals evaluated for the branches representing the possible outcomes connected to the vertex representing the respective conditional operator.

5. The apparatus according to claim 1, wherein the processing circuitry is to execute the machine-readable instructions to propagate the conditions imposed by the respective outcomes through the graph.

6. The apparatus according to claim 1, wherein the processing circuitry is to execute the machine-readable instructions to apply at least one optimization algorithm on the respective branches representing the possible outcomes, with the optimization algorithm being based on the condition imposed by the corresponding outcome.

7. The apparatus according to claim 6, wherein a condition-dependent branch-specific optimization is applied on the respective branches.

8. The apparatus according to claim 1, wherein the processing circuitry is to execute the machine-readable instructions to detect at least one dead branch within the graph-based representation based on the condition or conditions the vertices of the branch are annotated with.

9. The apparatus according to claim 1, wherein the respective branches representing the possible outcomes are data paths.

10. The apparatus according to claim 1, wherein the processing circuitry is to execute the machine-readable instructions to annotate at least the subset of the vertices of the respective branches representing the possible outcomes with the condition imposed by the corresponding outcome by inserting a third set of vertices representing the conditions into the graph and inserting edges between the vertices being annotated and the vertices representing the respective conditions.

11. The apparatus according to claim 1, wherein the graph representation is a data-flow graph representing the circuit.

12. The apparatus according to claim 1, wherein the graph representation is based on an equivalence graph.

13. The apparatus according to claim 1, wherein the processing circuitry is to execute the machine-readable instructions to generate the graph representation from a further RTL representation of the circuit.

14. The apparatus according to claim 1, wherein the processing circuitry is to execute the machine-readable instructions to determine, for one or more operators represented by the one or more vertices of the first set of vertices of the graph, one or more logically equivalent operators, include the one or more logically equivalent operators in the graph representation, such that the graph representation comprises a plurality of logically equivalent representations of the circuit, and generate the RTL representation of the circuit based on one of the plurality of equivalent representations of the circuit.

15. The apparatus according to claim 14, wherein the processing circuitry is to execute the machine-readable instructions to determine the respective one or more logically equivalent operators based on at least one condition the vertex of the respective operator is annotated with and/or based on at least one condition a vertex inside a branch connected to the vertex of the respective operator is annotated with.

16. The apparatus according to claim 14, wherein the processing circuitry is to execute the machine-readable instructions to select one representation from the plurality of logically equivalent representations of the circuit based on a selection criterion, and to generate the RTL representation based on the selected representation.

17. The apparatus according to claim 16, wherein the selection criterion is based on at least one of an implementation cost of the representation, a silicon area required by the representation, a power consumption of the representation and on a processing delay of the representation.

18. The apparatus according to claim 14, wherein the processing circuitry is to execute the machine-readable instructions to determine the one or more logically equivalent operators based on a pre-defined set of logically equivalent transformations between operators.

19. A method for generating a register transfer level (RTL) representation of a circuit, the method comprising:
generating a graph representation of the circuit, the graph representation comprising a first set of vertices representing operators and a second set of vertices representing operands of the graph representation of the circuit;
identifying one or more conditional operators, with each conditional operator defining at least two possible outcomes depending on the condition, and with each possible outcome being represented by a branch of the graph representation of the circuit;
determining, for the possible outcomes of the one or more conditional operators, a condition imposed by the respective outcome;
annotating at least a subset of the vertices of the respective branches representing the possible outcomes with the condition imposed by the corresponding outcome; and
generating an RTL representation of the circuit based on the graph representation of the circuit.

20. A non-transitory, computer-readable medium comprising a program code that, when the program code is executed on a processor, a computer, or a programmable hardware component, causes the processor, computer, or programmable hardware component to perform the method of claim 19.
